(19) United States
(12) Patent Application Publication
(10) Pub. No.: US 2023/0399736 A1
(43) Pub. Date: Dec. 14, 2023

(54) A METHOD AND A SYSTEM FOR GENERATING A HIGH-RESOLUTION PATTERN ON A SUBSTRATE

(71) Applicant: Teknologian tutkimuskeskus VTT Oy, Espoo (FI)

(72) Inventors: Jaakko LEPPÄNIEMI, VTT (FI); Asko SNECK, VTT (FI)

(73) Assignee: Teknologian tutkimuskeskus VTT Oy, Espoo (FI)

(21) Appl. No.: 18/035,765

(22) PCT Filed: Nov. 17, 2021
(86) PCT No.: PCT/FI2021/050778

§ 371 Date: May 8, 2023

(30) Foreign Application Priority Data
Nov. 20, 2020 (FI) 20206184
Mar. 30, 2021 (FI) 20215371

(51) Int. Cl. C23C 16/04; C23C 14/04; G03F 7/16

(52) U.S. Cl. CPC C23C 16/04; C23C 14/04; G03F 7/16; H01L 21/3105

(57) ABSTRACT

The present invention relates to a method and an apparatus for manufacturing of a desired pattern of an electrically conducting, semiconducting or insulating material on a substrate. A patterned polymer ink film (22′) is produced out of a semi-dry polymer ink by bringing a three-dimensional relief pattern with a positive image of the desired pattern (25) temporarily into contact with the semi-dry polymer ink film (22) so that portions (22″) of the semi-dry polymer ink film (22) are transferred to the three-dimensional relief pattern (25). The patterned polymer ink film with the negative of the desired pattern (22′) has vertical sidewalls caused by fracturing of the semi-dry polymer ink film (22) with cohesion by the edges of the three-dimensional relief pattern (25) and adhesion between the second portions (22″) of the semi-dry polymer ink film (22) and the three-dimensional relief pattern (25). The patterned polymer ink film (22′) is transferred onto a substrate (26), and a conductive, semi-conductive or insulating material layer (30′) is deposited onto the substrate (26) using physical vapor deposition or chemical vapor deposition. The patterned polymer ink film (22′) is dissolved from the substrate (26) with an organic solvent to yield the desired pattern (30).

### FIELD

The present invention relates to a method and a system related to forming high-resolution patterns. More particularly, the invention relates to a method and a system suitable for printing-based patterning of electronic materials with high electrical performance, such as conductors, semiconductors and dielectrics, on a substrate.

### BACKGROUND

Although printed electronics has advanced in the last decades in terms of printing resolution and printed device performance, there is a fundamental lack of electronic materials that could be printed. Such materials include reactive metals such as aluminum or titanium that cannot be formed as conductive inks due to their rapid oxidation in air that forms thin and dense oxide layer that prevents conductivity. Such materials provide for example low-work function and Ohmic contacts to n-type semiconductors that are used in thin film transistors, solar cells, and organic light emitting diodes. In addition, several other materials such as metal oxides in oxide semiconductors (e.g. indium gallium zinc oxide, IGZO), transparent conductive oxides (e.g. indium tin oxide, ITO) and insulating oxides (e.g. aluminum oxide Al₂O₃) suffer from lower performance when they are formed from printed inks when compared to fabricating the same materials using a conventional vacuum deposition process, such as evaporation, sputtering etc.

Thus, a method is needed that enables a combination of high-performance materials, such as conductors, semiconductors and dielectrics, and printing-based patterning. Such method would enable bridging a gap existing between the materials provided by the current printed electronics and the demands of the electronic industry.

### DESCRIPTION OF THE RELATED ART

Printing nanoparticle-based conductor layers, discussed for example in “Top-gate staggered poly(3,3′″-dialkyl-quarterthiophene) organic thin-film transistors with reverse-offset-printed silver source/drain electrodes” by Kim, Minseok; Koo, Jae Bon; Baeg, Kang-Jun; Jung, Soon-Won; Ju, Byeong-Kwon; You, In-Kyu, published in journal Applied Physics Letters (2012), 101(13), 133306/1-133306/5; ISSN: 0003-6951, has been explored as one possible solution. For achieving high conductivity, precious metals such as silver (Ag) or even gold (Au) need to be used, since lower cost metals such as aluminum and copper oxidize easily, which prevents use thereof in conductive nanoparticle inks. However, manufacturing of precious metal nanoparticle inks suitable for printing is very expensive. Cost of the precious metal ink is significantly higher than cost of the precious metal as such. Thus, variations of nanoparticle-based printing methods are not suitable for manufacturing electronic devices on any cost-conscious markets.

Printed patterning methods of vacuum-deposited layers have been developed to solve the problem of limited availability of printed materials. Printed lift-off and printed wet etching using gel-based etchants are methods drawing from conventional nnicrofabrication methods. However, these printed patterning methods suffer from “edge ears” of the deposited material. In the case of lift-off, when the resist layer is printed using conventional printing techniques, such as inkjet, screen or gravure printing, the resulting resist pattern will have slanted sidewalls. Such slanted sidewalls will lead to edge ears (10) of the deposited material. Edge ears (10) of the deposited material, in this example a deposited metal pattern, are illustrated by a height profile shown in the FIG. 1. Furthermore, height of the metal layer (11) also shows significant variation. In the case of printed etching, similar edge ears are formed from residual material that has only partially reacted with the etchant. In addition, the method leads to high line edge roughness and porous edge that arise from the uneven spreading of the printed etchant on the deposited material, which ultimately limits the attainable linewidth resolution.

Patent application US20060105492A discloses a method for forming an electronic organic device where a pattern is printed onto a substrate and used as a sacrificial mask to remove any subsequent coated layers. Images and description in the publication suggest slanted sidewalls of the lift-off ink, which will cause the edge ear problem described above.

Nanoimprint lithography (NIL) has been developed since mid-90's to enable high-resolution patterns (<1 μm) without the need of electron-beam lithography, discussed for example in “Nanoimprint lithography resist profile inversion for lift-off applications” by Shields, Philip A.; Allsopp, Duncan W. E., published in journal Microelectronic Engineering (2011), 88(9), 3011-3014; ISSN: 0167-9317. The NIL method has been scaled to continuous roll-to-roll production and is investigated for the use in printed electronics. In NIL, a polymer resist layer on a substrate is embossed using a mold fabricated in a silicon (Si) wafer or quartz glass and the deformation is stored in the resist either under heating or using ultraviolet radiation (UV radiation), the process thus referred to as UV-NIL. A typical cross-sectional shape of the patterned resist is a tapered structure due to the deformation of the resist under the embossing pressure. The patterned resist layer is then used as (i) an etching mask to pattern the layer below the resist, or (ii) used as a lift-off layer for patterning subsequently deposited material. In the first case, the method requires the use of additional etching step, such as reactive ion etching (RIE), and often results in unwanted residual resists. In the second case, the successful use of NIL in lift-off without edge ears requires utilization of bi-layer resists and a two-step lift-off process due to the tapered sidewalls of the imprinted resist.

Somewhat different approach has been taken with nanotransfer printing (nTP), disclosed for example in “Repeatable and metal-independent nanotransfer printing based on metal oxidation for plasmonic color filters”, by Hwang, Soon Hyoung; Zhao, Zhi-Jun; Jeon, Sohee; Kang, Hyeokjung; Ahn, Junseong; Jeong, Jun Ho published in Journal Nanoscale (2019), 11(23), 11128-11137; ISSN: 2040-3372. In nTP, the deposited metal layers are transferred from patterned polydimethylsiloxane (PDMS) stamp to the substrate with the help of self-assembled monolayers (SAM) on the receiving substrate that provide strong adhesion to the deposited metal layer or using a low-surface energy such as fluoropolymer release layer on the stamp. However, this method is limited to metals (only Au, Ag and Al have been demonstrated), is not readily scalable and, in some cases, requires the use of an adhesive layer underneath the transferred material. This can be detrimental to some applications requiring multilayer devices such as top contacts to electronic devices, where the remaining adhesive layer can act as tunneling barrier or charge trap and prevent good charge injection to the underlying layer. Furthermore, nano-transfer printing is very slow, since the process requires SAM-treatments that require typically at least one hour for completion, and therefore not suitable for mass production.

The state-of-the-art above can be summarized that a printed patterning method of vacuum deposited layers is needed that allows the high-resolution patterning of structures from various materials without edge ears, rough edges or need of adhesive layers. This method would enable the use of vacuum-deposited materials that are either i) not printable using known methods, ii) have poor performance when they are printed using known methods, or iii) are expensive when they are printed.

FIG. 2 shows definition of taper angle θ of a structure (17) on a substrate (26). Taper angle can be defined with equation

$$θ = {tan}^{- 1} ( \frac{{w}_{bottom} - {w}_{top}}{2 d} )$$

where w_{bottom} represents width of the structure (17) at its bottom, at the surface of the substrate (26), wₜₒₚ represents width of the structure (17) at the top face, furthest away from the bottom of the structure, attached to the substrate (26), and d represents height of the structure (17). When the structure is generated by patterning a film with a defined thickness, the height d can also be referred to as a thickness.

### SUMMARY

An object is to provide a method and apparatus so as to solve the problem of providing a method that enables printing-based forming of high-resolution patterns from a variety of different materials. The objects of the present invention are achieved with a method according to the claim 1. The objects of the present invention are further achieved with an apparatus according to the claim 7.

The preferred embodiments of the invention are disclosed in the dependent claims.

The present invention is based on the idea of patterning of a semi-dry polymer ink film using reverse-offset for forming vertical sidewalls in a printed polymer layer. Material of the final structure is directly deposited on the surface of the substrate with the patterned polymer film, and thus there is no need for adhesive layers and thus the method is applicable also to manufacturing multilayer devices including top contacts. Semi-dry condition of the polymer film facilitates fracturing of the polymer film during preparation of the patterned polymer ink film with a negative of a desired pattern, and this fracturing causes the vertical sidewalls in the patterned semi-dry polymer ink film.

The present invention has the advantage that it enables low-cost forming of high quality conductive high-resolution structures on various substrates. It enables using printing for defining patterns of any material, including reactive metals such as aluminum (Al), titanium (Ti) and molybdenum (Mo), that cannot be used in nanoparticle inks, as well as semiconductors and insulating dielectric layers. Vertical sidewalls of the polymer layer with sharp edges allow the deposited material to be patterned with high-resolution, with low edge roughness and without forming “edge ears” on edges of the sidewalls that would arise from the material deposited on the inclined walls of the patterned layer. The method can be combined with various deposition techniques and has potential to achieve high resolution over large areas. With high resolution we refer to patterns with down to less than 1 μm line width, for example 0.5 μm, 0.25 μm or even 0.1 μm. Layer thickness of the generated pattern is uniform, and electrical characteristics of the generated structures are typical for high-quality vacuum processed films and reproducible without need for annealing the structure.

### BRIEF DESCRIPTION OF THE DRAWINGS

In the following the invention will be described in greater detail, in connection with preferred embodiments, with reference to the attached drawings, in which

FIG. 1 is a schematic showing some problems of prior art.

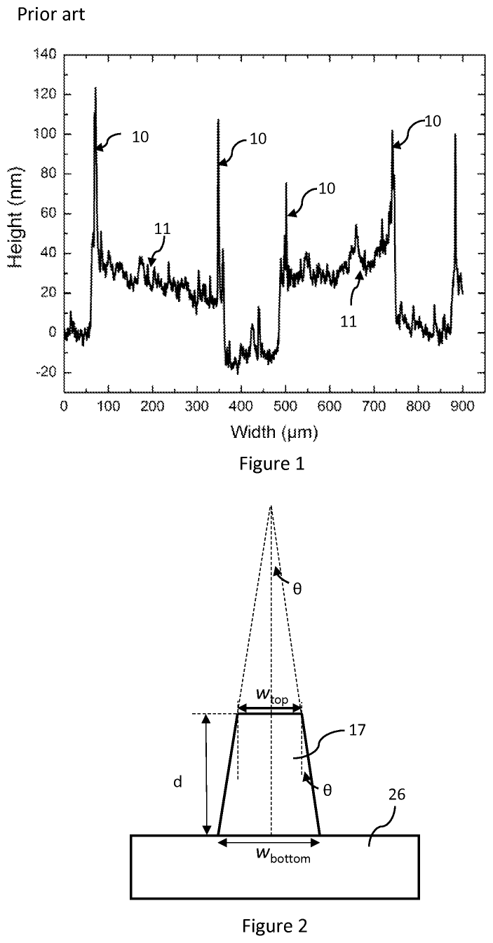

FIG. 2 illustrates definition of a taper angle.

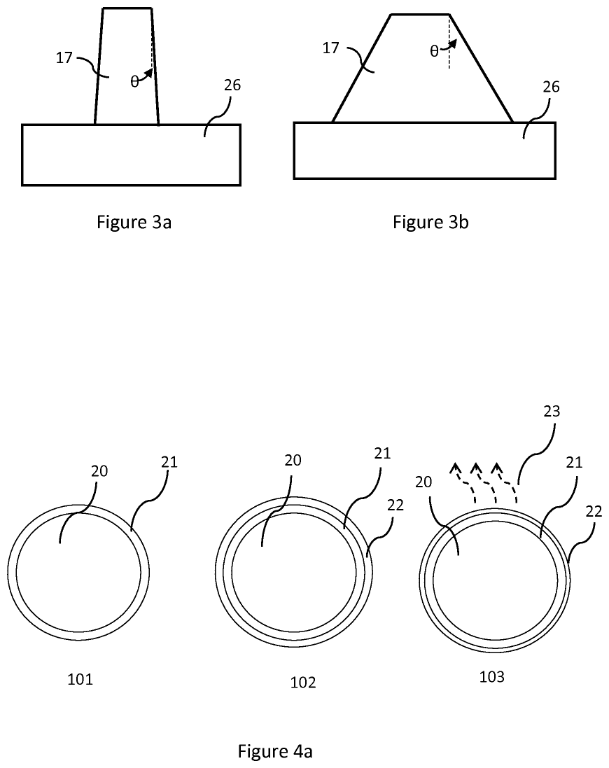

FIG. 3a illustrates a structure with vertical sidewalls.

FIG. 3b illustrates a structure with slanted sidewalls.

FIGS. 4a to 4g illustrate schematically an exemplary process according to the invention.

FIGS. 5a to 5e illustrate printed test patterns with different line widths.

FIGS. 6a to 6e illustrate height profiles measured from test patterns.

### DETAILED DESCRIPTION

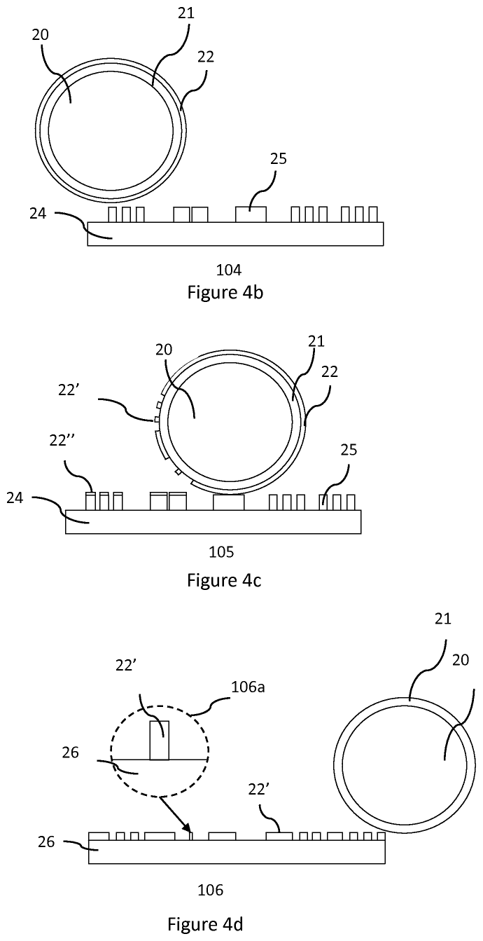

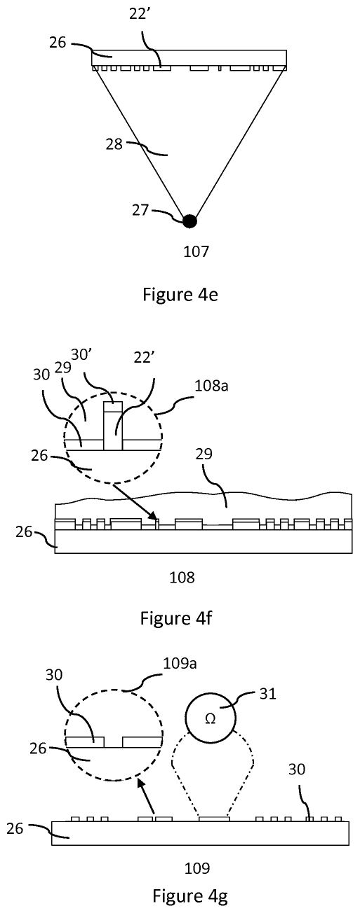

The FIG. 3a illustrates a structure (17) on a substrate (26), the structure (17) having vertical sidewalls. In this context, the term vertical sidewall refers to a sidewall of a structure that has a taper angle that between −° and 20°, preferably between −15° and 15°, more preferably between −10° and 10°, and most preferably between −5° and 5°. The FIG. 3b illustrates a structure (17) that has slanted sidewalls. Slanted sidewalls have a taper angle that is greater than the taper angle of the structure with vertical sidewalls. In practice, taper angle of slanted sidewalls is typically more than 20°. The structure (17) may represent for example a patterned polymer ink or a deposited structure.

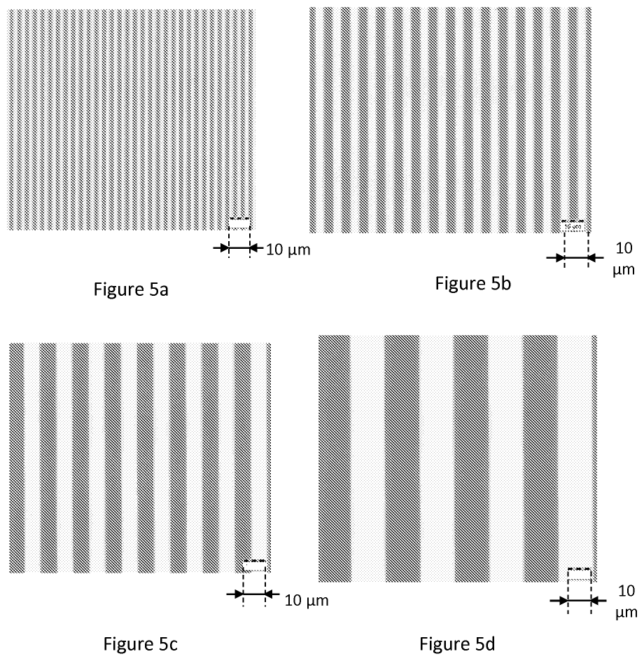

FIGS. 4a to 4g illustrate schematically an exemplary process according to the invention. Drawings are not in scale.

FIG. 4a illustrates an exemplary preparation step preceding the printing process. In the step 101, outer surface of a roller (20), preferably formed as a cylinder and illustrated in this figure with a side view thereof, is coated with a low-surface energy absorptive material (21) such as polydimethylsiloxane (PDMS). In a typical application, such coating may be performed by applying a so called PDMS blanket on the outer surface of the roller (20). As known in the art, the PDMS blanket may comprise a plastic film with PDMS coating. Instead of PDMS, any suitable alternative the low-surface energy absorptive materials (21) known in the art may be used.

In the exemplary step 102, the low-surface energy absorptive material (21) coating layer on the roller (20) and is further coated with a film of ink comprising of a polymer dissolved in at least one solvent. The ink may be referred in short as a polymer ink (22). For facilitating this step of coating the roller with the polymer ink (22), the polymer ink (22) should be in liquid form, thus easily spreadable into a thin film with essentially even thickness.

In the step 103, the polymer ink (22) is let to reach semi-dry condition by partial solvent absorption to the low-surface energy absorptive material (21) and/or by partial evaporation (23). In the semi-dry condition, cohesion of the polymer ink (22) is high in comparison to the polymer ink when in liquid form, and the semi-dry polymer ink also has high adhesion, i.e. it is “sticky”. Instead of the exemplary method steps 101 and 102, any applicable method capable of generating a film of semi-dry polymer ink (22) on the outer surface of the roller (20) may be used. The ink may comprise of a single solvent, but for controlling the printing process, for example time needed for the polymer ink (22) to reach the semi-dry condition, the polymer ink (22) may comprise more than one solvent. For example, the polymer ink (22) may, upon the coating phase, comprise two different solvents with different evaporation and/or absorption characteristics so that the semi-dry condition can be achieved mainly by partial evaporation and/or partial absorption of one of the solvents, while the other solvent evaporating and/or absorbing slower remains to maintain the polymer ink (22) in a semi-dry condition over a sufficient period of time to perform further steps of the manufacturing process. High cohesion of the semi-dry polymer ink (22) is important for enabling successful patterning of the polymer ink in the later steps of the method.

In the step 104, illustrated in the FIG. 4b, a patterned plate (24) is provided. The patterned plate (24) has a high-resolution 3D structure (25), where portions defining a positive image of a desired pattern, referred to as first portions or raised portions, are on a first horizontal level and remaining portions of the high-resolution 3D structure (25), referred to as the second portions of the recessed portions, are recessed below the first horizontal level. The patterned plate, in particular the portions thereof that are on the first horizontal level is brought to contact with the film of semi-dry polymer ink (22). This high-resolution 3D structure (25) may be pre-prepared for example using photolithography and etching, or electron beam lithography and etching and/or additive methods known in the art or any other method capable of producing high-resolution pattern on any suitable material, for example silicon, glass, metal or plastic. The high-resolution 3D structure (25) is preferably of resilient material so that it may be re-used several times for patterning several samples of polymer ink (22) in the semi-dry condition.

In the step 105, illustrated in the FIG. 4c, the roller (20) coated with the film of polymer ink (22) in semi-dry condition is rotated to bring the film of semi-dry polymer ink (22) temporarily in contact with the high-resolution 3D structure (25) so that portions (22″) of the semi-dry polymer ink that come into contact with the raised portions of the high-resolution 3D structure (25) attach to the raised portions of the high-resolution 3D structure (25) on the patterned plate (24) and are thereby removed. Optimal adhesion, in other words stickiness, of the semi-dry polymer ink film (22) facilitates this attaching step. Portions of the semi-dry polymer ink that coincide with the recessed portions of the high-resolution 3D structure (25) do not come into contact with the high-resolution 3D structure (25) and are thus left attached to the roller (20). Thus, a negative image of the desired pattern remains on the patterned polymer ink film (22′) that remains attached on the outer surface of the roller (20). This process has been found to produce vertical sidewalls on the patterned polymer ink film (22′) remaining on the roller (20).

To form the vertical sidewalls on the patterned polymer ink film (22′), the shear and tensile cohesion of the semi-dry polymer ink (22) and the surface energies of the semi-dry polymer ink (22) and the raised area of the high-resolution 3D structure (25) that control the work of adhesion need to be optimized. First, the adhesion of the semi-dry polymer ink (22) to the low-surface energy absorptive material (21) needs to be larger than the shear cohesion of the semi-dry polymer ink (22) to allow the semi-dry ink to separate into first portions residing on the outer surface of the roller, referred to as the patterned polymer ink film (22′) and second portions attached on the raised area of the 3D structure (22″). The effect of the shear cohesion can be reduced by suitable impression of the raised area of the 3D structure (25) to the semi-dry polymer ink (22) to produce fracture in the semi-dry polymer ink by high, localized stress at the edges of the raised area. Sharpness of edges of the features of the raised area of the 3D structure (25) is beneficial for inducing the fracture. Further, the tensile cohesion of the semi-dry polymer ink (22) needs to be larger than the adhesion of the semi-dry polymer ink to the low-surface energy absorptive material (21) to prevent the semi-dry polymer ink (22) from splitting inside the film during the patterning. In addition, the work of adhesion of the semi-dry polymer ink (22) needs to be larger to the raised area of the 3D structure (25) than to the low-surface energy absorptive material (21) to allow parts (22″) of the semi-dry polymer ink (22) to transfer to the raised area of the 3D structure (25). This patterning process that is based on fracturing of the film of semi-dry polymer ink with high cohesion produces the vertical sidewalls into the patterned polymer ink film (22′). Vertical sidewalls of the patterned polymer ink film facilitate generation of vertical sidewalls into the final, deposited structure and/or avoid generation of edge ears. Tests performed using physical deposition methods show that the deposited structure has vertical sidewalls. This is in contrary to known printing methods where the patterning of the polymer ink is performed in the liquid condition of the polymer ink with low viscosity and low cohesion that leads to slanted sidewall profile, which is determined mostly by the ink-substrate surface interactions (wetting). In this context, sidewalls of the patterns of the patterned polymer ink film (22′) are considered to be vertical when having taper angle between −20° and 20°, preferably between −15° and 15°, more preferably between −10° and 10° and most preferably between −5° to 5°. The slanted sidewalls leading to “edge ears” typically have a taper angle of more than 20°.

In the step 106, illustrated in the FIG. 4d, the patterned polymer ink film (22′) having vertical sidewalls is further transferred to a substrate (26) by rotating the roller (20) so that the patterned polymer ink film (22′) comes into contact with the substrate (26) and attaches to it directly while detaching from the low-surface energy absorptive material (21) on the surface of the roller (20). The transferred patterned polymer ink film (22′) now forms a negative of the desired pattern on the face of the substrate (26). Enlargement 106a illustrates a part of the patterned polymer ink film (22′) attached on the substrate (26). In this step, the work of adhesion of the semi-dry polymer ink (22) needs to be larger to the substrate (26) than to the low-surface energy absorptive material (21) to allow successful transfer of the semi-dry polymer ink to the substrate.

Any surface treatment method known in the art may be applied on any of the surfaces, including the PDMS, the 3D high-resolution structure and/or the substrate, between the phases of the method for increasing or adjusting surface properties, such as surface energy or adhesion, of the respective surface(s). Preferably, the patterned polymer ink film (22′) attached on the substrate (26) is allowed to dry before it is subjected to the next step. During this period, the one or more solvent is further evaporated. During the drying phase, the patterned polymer ink film (22′) on the substrate (26) may be subject to heating to speed up the drying process. As a result, the solvent(s) may be fully evaporated from the patterned polymer ink film (22′), which thus may be considered to be in a dry condition. The patterns on the patterned polymer ink film (22′) have vertical sidewalls also when the ink is in dry condition.

In the step 107, illustrated in the FIG. 4e, the resulting polymer ink pattern (22′) with the negative of the desired pattern is used as mask in a physical vapor deposition process, in which a layer of conductive metal, semiconductor or dielectric material is deposited onto the substrate. Any suitable physical vapor deposition method known in the art may be used in this step, such as sputtering, resistive or thermal evaporation, electron beam evaporation, pulsed laser deposition, and/or sublimation and best applicable method may depend on the material applied and also wanted electrical characteristics thereof. In the exemplary embodiment shown in the FIG. 4e, an evaporation source (27) produces an evaporation plume (28) to perform the evaporation. In this non-limiting example, the material deposited by evaporation is metal. Even non-directional vacuum deposition methods, such as sputtering, can be used when the sidewalls of the polymer ink pattern (22′) on the substrate (26) are vertical. Alternatively, a chemical vapor deposition method, such as atomic layer deposition (ALD), plasma-enhanced atomic layer deposition, photo-assisted atomic layer deposition, UV-assisted atomic layer deposition, spatial atomic layer deposition, epitaxial growth, atomic layer epitaxy, molecular beam epitaxy, molecular layer deposition, metalorganic vapor deposition, plasma-enhanced chemical vapor deposition, remote plasma-enhanced chemical vapor deposition, or photo-initiated chemical vapor deposition. During the deposition step, regardless of the deposition method, temperature should be kept below the thermal decomposition of and/or cross-linking temperature of the polymer resist to avoid damage to the polymer layer and below the onset of outgassing that would disturb the film growth. As known in the art, exact temperature is dependent on the resist material. For example, when polyvinylphenol is used as the resist material, the temperature can be kept below 110° C. to avoid thermal decomposition and cross-linking. The reaction temperature may be lowered, for example, by use of photo-assisted, UV-assisted or plasma-assisted atomic layer deposition. The deposition process may be performed in vacuum using conventional atomic layer deposition or at atmospheric pressure using spatial atomic layer deposition. The choice of the chemical vapor deposition method may depend on the reaction temperature, on the material applied and also on wanted electrical characteristics thereof.

In the step 108, illustrated in the FIG. 4f and in the enlargement 108a, the patterned polymer ink film (22′) having the negative of the desired pattern is removed from the substrate (26) by dissolving it with an organic solvent (29) such as alcohol, including but not limited to methanol, ethanol or isopropanol, or other organic solvents such as propylene glycol methyl ether acetate (PGMEA), ethyl acetate or acetone, which will remove both the patterned polymer ink film (22′) and portions of the deposited material (30′), such as metal, semiconductor or insulator, residing on top of the patterned polymer ink film (22′). Selection of the solvent (29) depends on the polymer used in the polymer ink, as known by a person skilled in the art.

The step 109, illustrated in the FIG. 4g and enlargement 109a, illustrates the final result of the printing process, in which the desired pattern (30) of the deposited material has been formed on the substrate (26) the pattern now having vertical sidewalls when deposition was performed using physical vapor deposition. If the desired pattern (30) is a conductor pattern, as in the exemplary process, electrical characteristics such as resistance and/or conductivity thereof may be measured with an electrical meter (31) as further illustrated in the step 109.

Due to the vertical sidewalls of the patterned polymer ink film (22′) the remaining desired pattern made of the patterned material (30) is generated without “ears” on the edges of the sidewalls of the patterned material.

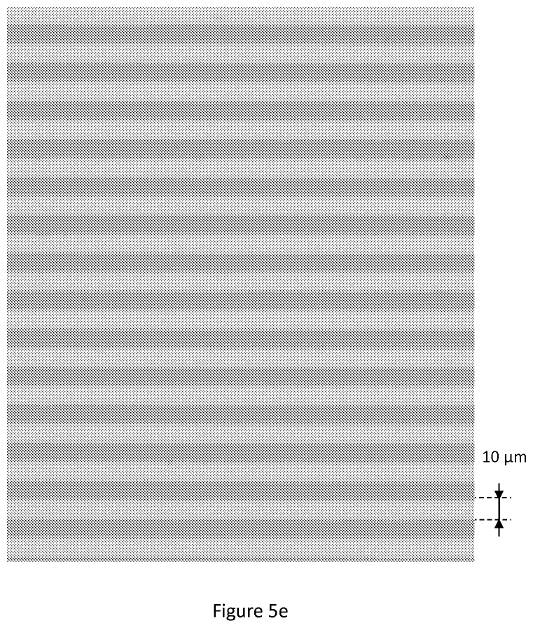

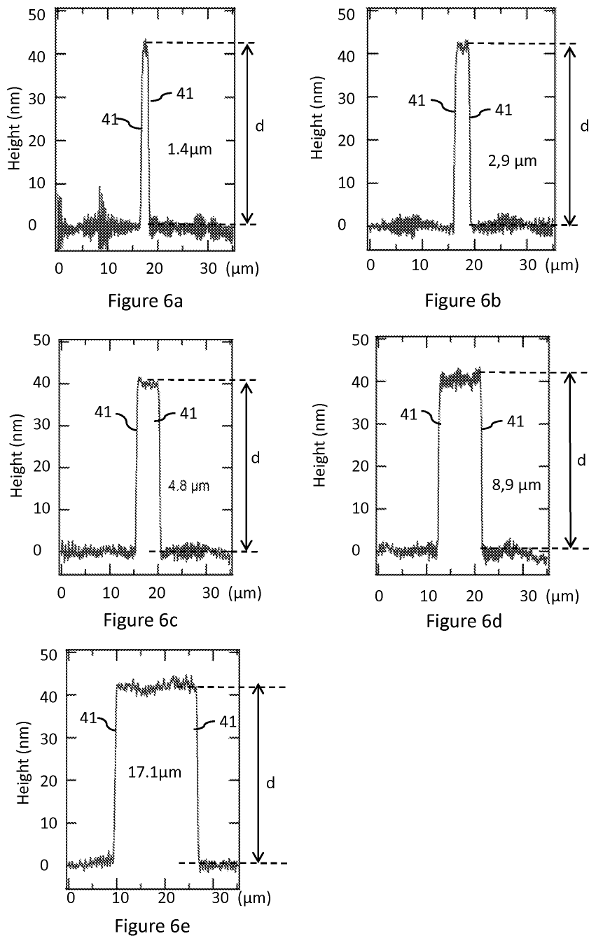

FIGS. 5a to 5d illustrate exemplary test patterns generated using the invented printing method. Generated patterns comprise stripes with predefined linewidth ranging from less than 2 μm to more than 15 μm. All test prints presented here were performed using like parameters, including at least approximately similar height of the coated polymer ink layer and the same height of the deposited material layer, wherein height of the deposited material layer was primarily controlled by the deposition rate and time used for the deposition step. The deposition rate and the deposited layer thickness were measured using a quartz crystal microbalance. Each test pattern was tested for printing in 0 degrees, 45 degrees and 90 degrees angle with respect to rolling direction of the roller (20) about its central axis to test whether inclination direction of the printed line patterns would have effects on quality of the resulting structures. The test runs show that the method is independent of relative directions of the rolling direction and the edges of the printed pattern. Tests were performed for example by deposition layers of indium tin oxide (ITO), as an example of a metal oxide, and by sputtering and layer of silicon monoxide (SiO), as an example of a dielectric, by evaporation. Further tests were performed using ALD, as an example of an applicable chemical vapor deposition method. In one exemplary test, a layer of Al₂O₃ was successfully deposited at 110° C. temperature and patterned. FIG. 5e shows a microscope image of a test pattern implemented using ALD. The exemplary, striped test pattern comprises deposited pattern with 10 μm line width, and a 10 μm gap between the patterns. When ALD deposition is used, it is preferable that thickness of the ALD deposited pattern layer is less than thickness of the resist layer. For example, thickness of the resist layer should be at least 1.5 times the thickness of the deposited layer, and preferably about 2 times the thickness of the deposited layer. In one specific example, where Al₂O₃ was deposited using ALD, a good result was achieved with 80 nm resist layer thickness and Al₂O₃ deposited onto layer thickness of 40 nm. Sidewalls of the ALD deposited pattern are slanted in comparison to sidewalls of the deposited pattern achieved using physical deposition due to tendency of fracturing of the edges of the ALD deposited structure during removal of the resist. Tests indicate that overall shape of the ALD-deposited pattern is however accurate and edge ears are avoided. FIGS. 6a to 6e illustrate results of the tests, showing measured height profiles of cross-sections of the resulting desired metal patterns on the substrate, comprising examples shown in the FIGS. 5a to 5d, with predefined linewidths ranging from 1.4 μm to 17.1 μm. It should be noticed that height on y-axis is measured in nanometers, while width on x-axis is measured in micrometers. Height refers to thickness of the material layer of the desired structure, and zero height corresponds to the top surface of the substrate. Vertical sidewalls (41) of the patterns are sharp and accurate, and no visible “ears” are formed on the edges of the sidewalls. Also, thickness (d) of the generated pattern is essentially constant and, in particular, independent of the line width of the test pattern.

For confirming quality of the evaporation deposited aluminum (Al) metal patterns generated using the invented method, the electrical characteristics of the structures shown in the FIGS. 5a to 5d were also measured. Measured sheet resistance of the resulting metal structure was found to be similar to what is achieved with silver structures printed using nanoparticle silver ink, which is currently about thousand times more expensive than aluminum used in the evaporation.

Invented method enables producing structures for various applications using a variety of materials. A non-limiting list of exemplary patterns comprises visually invisible or transparent metal grids for applications such as touch panels, heater films, antennas and photovoltaic current collectors, metal oxide, organic, carbon nanotube, graphene, polycrystalline Si or amorphous Si thin-film transistor source/drain and/or gate electrodes, metal oxide patterns for metal oxide thin-film transistors, diodes or resistive random access memories, patterns for passive components such as resistors, inductors or capacitors, metamaterials, plasmonic structures, filters, absorbers, optical codes, interdigitated electrodes for sensors such as gas, humidity and/or biosensors, transparent ITO antennas and ITO layers for touch screens. As known in the art, transparency and/or invisibility to human eye of structures and patterns made of non-transparent material can be achieved by using line widths, which are invisible to human eye, i.e. line widths of about 1 μm or less.

In a first exemplary process, the polymer ink used was 4 wt % polyvinylphenol dissolved in ethyl acetate at 60° C. After deposition, the polymer ink pattern was dissolved using methanol. In a second exemplary process, the polymer ink was a 5 wt % polyvinylpyrrolidone dissolved in butanol at room temperature. After deposition, the polymer ink pattern was dissolved using propylene glycol monomethyl ether acetate (PGMEA). In a third exemplary process, the polymer ink used was 4 wt % polyvinylphenol dissolved in ethyl acetate at 60° C. and 4 wt % polyvinylphenol dissolved in ethyl lactate which were mixed in 7 to 15 ratio for controlling achieving of the semi-dry condition of the polymer ink. Ethyl lactate has higher boiling point and lower vapor pressure than ethyl acetate and will evaporate slower. After the deposition, the polymer ink pattern was dissolved using methanol.

It is apparent to a person skilled in the art that as technology advanced, the basic idea of the invention can be implemented in various ways. The invention and its embodiments are therefore not restricted to the above examples, but they may vary within the scope of the claims.

1. A patterning method for manufacturing of a desired pattern of an electrically conducting, semiconducting or insulating material on a substrate, the method comprising:
providing a semi-dry polymer ink film on top of a polydimethylsiloxane surface of a roller, wherein the polymer ink comprises a polymer dissolved in at least one organic solvent;
producing a patterned polymer ink film having form of a negative of the desired pattern defined by first portions of the semi-dry polymer ink film remaining on top of the polydimethylsiloxane surface of the roller, wherein the patterned polymer ink film is produced by bringing a three-dimensional relief pattern with a positive image of the desired pattern temporarily into contact with the semi-dry polymer ink film so that second portions of the semi-dry polymer ink film are transferred to the three-dimensional relief pattern, and wherein the patterned polymer ink film has vertical sidewalls caused by fracturing of the semi-dry polymer ink film at the edges of the three-dimensional relief pattern, wherein said fracturing is caused by cohesion of the semi-dry polymer ink film and adhesion between the second portions of the semi-dry polymer ink film and the three-dimensional relief pattern;
transferring the patterned polymer ink film from the polydimethylsiloxane surface of the roller onto a substrate to produce a negative of the desired pattern on the substrate, wherein the negative of the desired pattern on the substrate has said vertical sidewalls;
depositing a conductive, semi-conductive or insulating material layer onto the face of the substrate with the negative of the desired pattern, using physical vapor deposition or chemical vapor deposition; and
dissolving the negative of the desired pattern using an organic solvent to yield the desired pattern formed by the deposited conductive, semi-conductive or insulating material on the substrate.

2. The patterning method according to claim 1, wherein the three-dimensional relief pattern comprises raised portions and recessed portions, the upper surface of the raised portions being on a first horizontal level and the recessed portions being recessed below said first horizontal level,
and wherein said step of producing the patterned polymer ink film comprises
transferring second portions of the semi-dry polymer ink film to the raised portions of the three-dimensional relief pattern that come into contact with the semi-dry polymer ink film by bringing the second portions temporarily into contact with the raised portions, wherein first portions of the semi-dry polymer ink film that do not come into contact with the three-dimensional relief pattern remain attached on the polydimethylsiloxane surface to form said patterned polymer ink film.

3. The method according to claim 1, wherein the step of providing a semi-dry polymer ink film on top of a polydimethylsiloxane surface comprises:
coating a polydimethylsiloxane surface using a polymer ink in liquid form, the polymer ink comprising a polymer dissolved in at least one organic solvent; and
allowing the polymer ink to reach semi-dry condition via partial evaporation of at least one of the at least one organic solvent and/or partial absorption of at least one of the at least one organic solvent onto the polydimethylsiloxane film.

4. The method according to claim 1, wherein in the step depositing, the conductive, semi-conductive or insulating material is deposited both on the substrate and onto the negative of the desired pattern, and wherein the step of dissolving comprises detaching and removing any conductive, semi-conductive or insulating material deposited onto the negative of the desired pattern by said dissolving the negative of the desired pattern.

5. The method according to claim 1, where in the step of depositing is performed using a physical vapor deposition method, such as resistive evaporation, thermal evaporation, e-beam evaporation, pulsed laser deposition, sublimation or sputtering, or a chemical vapor deposition method, such as atomic layer deposition, plasma-enhanced atomic layer deposition, photo-assisted atomic layer deposition, UV-assisted atomic layer deposition, spatial atomic layer deposition, epitaxial growth, atomic layer epitaxy, molecular beam epitaxy, molecular layer deposition, metalorganic vapor deposition, plasma-enhanced chemical vapor deposition, remote plasma-enhanced chemical vapor deposition, or photo-initiated chemical vapor deposition.

6. The method according to claim 1, where the vertical sidewalls of the patterned polymer ink have taper angle between −20° and 20°, preferably between −15° and 15°, more preferably between −10° and 10°, and most preferably between −5° and 5°.

7. An apparatus for manufacturing of a desired pattern of an electrically conducting, semiconducting or insulating material on a substrate, the apparatus comprising:
a roller provided with a semi-dry polymer ink film on top of a polydimethylsiloxane surface disposed on its outer surface;
a three-dimensional relief pattern configured to produce a patterned polymer ink film having a form of a negative of the desired pattern defined by first portions of the semi-dry polymer ink film remaining on top of the polydimethylsiloxane surface on the roller, when the three-dimensional relief pattern is configured to be temporarily brought into contact with the semi-dry polymer ink film so that second portions of the semi-dry polymer ink film are transferred to the three-dimensional relief pattern, wherein fracturing of the semi-dry polymer ink film at the edges of the three-dimensional relief pattern is configured to cause the patterned polymer ink film to have vertical sidewalls, wherein the fracturing is caused by cohesion of the semi-dry polymer ink film and adhesion between the semi-dry polymer ink and the three-dimensional relief pattern;
wherein the roller is further configured be brought into contact with a substrate for transferring the patterned polymer ink film from the polydimethylsiloxane surface onto the substrate to produce a negative of the desired pattern on the substrate, wherein the negative of the desired pattern on the substrate has said vertical sidewalls;
physical deposition means, such as resistive evaporation, thermal evaporation, e-beam evaporation, pulsed laser deposition, sublimation or sputtering means, or chemical deposition means, such as atomic layer deposition means, for depositing a conductive, semi-conductive or insulating material layer onto the face of the substrate with the negative of the desired pattern; and
dissolving means configured to introduce an organic solvent on the substrate with the vacuum deposited material layer for dissolving the negative of the desired pattern to yield the desired pattern formed by the deposited conductive, semi-conductive or insulating material on the substrate.

8. The apparatus according to claim 7, wherein the three-dimensional relief pattern comprises raised portions and recessed portions, wherein the upper surface of the raised portions is on a first horizontal level and the recessed portions being recessed below said first horizontal level, and
wherein the three-dimensional relief pattern is configured to define the negative of the desired pattern by causing transferring of second portions of the semi-dry polymer ink film to the raised portions of the three-dimensional relief pattern that come temporarily into contact with the semi-dry polymer ink film, and wherein first portions of the semi-dry polymer ink film that do not come into contact with the three-dimensional relief pattern remain attached on the polydimethylsiloxane surface, said first portions having the form of the negative of the desired pattern.

9. The apparatus according to claim 7, wherein the roller is configured to be provided with the semi-dry polymer ink film on top of a polydimethylsiloxane surface by:
coating the roller's polydimethylsiloxane surface with a layer of polymer ink comprising a polymer dissolved in at least one organic solvent; and
allowing the polymer ink to reach semi-dry condition via partial evaporation of at least one of the at least one organic solvent and/or partial absorption of at least one of the at least one organic solvent onto the polydimethylsiloxane film.

10. The apparatus according to claim 7, wherein the conductive, semi-conductive or insulating material is deposited both on the substrate and onto the negative of the desired pattern, and wherein the dissolving means is configured to detach and remove any conductive, semi-conductive or insulating material deposited onto the negative of the desired pattern by said dissolving the negative of the desired pattern.

11. The apparatus according to claim 7, wherein the vertical sidewalls of the patterned polymer ink have taper angle between −20° and 20°, preferably between −15° and 15°, more preferably between −10° and 10° and most preferably between −5° and 5°.

12. A substrate with a desired pattern, wherein the desired pattern is manufactured using the method according to claim 1, and wherein the desired pattern comprises any one of a visually transparent metal grid for a touch panel, a heater film, an antenna and/or a photovoltaic current collector, a metal oxide, organic, carbon nanotube, graphene, polycrystalline Si or amorphous Si thin-film transistor source, drain and/or gate electrode, a metal oxide pattern for metal oxide thin-film transistor, diode or resistive random access memory, a resistor, a capacitor, an inductor, a metamaterial, a plasmonic structure, a filter, an absorber, an optical code, an interdigitated electrode for a sensor, a visually transparent ITO antenna and an ITO layer for a touch screen.
